(19) United States
(12) Patent Application Publication
(10) Pub. No.: US 2026/0150608 A1
(43) Pub. Date: May 28, 2026

(54) SEMICONDUCTOR WAFER AND METHOD OF MANUFACTURING SEMICONDUCTOR WAFER

(71) Applicant: Mitsubishi Electric Corporation, Tokyo (JP)

(72) Inventors: Kyohei AKIYOSHI, Tokyo (JP); Takanori TANAKA, Tokyo (JP); Shun SATO, Tokyo (JP)

(73) Assignee: Mitsubishi Electric Corporation, Tokyo (JP)

(21) Appl. No.: 19/346,680

(22) Filed: Oct. 1, 2025

(30) Foreign Application Priority Data
Nov. 25, 2024 (JP) 2024-204451

(51) Int. Cl. H01L 21/304; H10D 62/10

(52) U.S. Cl. CPC H10P 52/00; H10D 62/117

(57) ABSTRACT

A semiconductor wafer according to the present disclosure is a semiconductor wafer having a first surface and a second surface opposite the first surface, wherein the first surface includes a first main surface and an enclosing surface enclosing a perimeter of the first main surface via a stepped surface and being set back from the first main surface toward the second surface, the semiconductor wafer has a first cut-out in a portion in a circumferential direction of the stepped surface connecting the first main surface and the enclosing surface, the semiconductor wafer has a second cut-out in a portion in a circumferential direction of an outer peripheral surface connecting the second surface and the enclosing surface, and the first cut-out is in the form of an orientation flat, and the second cut-out is in the form of a notch.

### BACKGROUND

### Technical Field

The present disclosure relates to a semiconductor wafer and a method of manufacturing a semiconductor wafer.

### Description of the Background Art

Japanese Patent Application Laid-Open No. 2021-52178 proposes a method of trimming an edge of a semiconductor wafer to form a protruding shape to reduce cracking and breakage at the edge when a semiconductor substrate has a device structure formed on a front side thereof and is thinned.

In Japanese Patent Application Laid-Open No. 2021-52178, the semiconductor wafer has the same orientation flat in an outer peripheral surface and in a protruding portion thereof. The orientation flat in the outer peripheral surface of the semiconductor wafer reduces a diameter of the semiconductor wafer, and the orientation flat in the protruding portion inside the outer peripheral surface further reduces a diameter of the protruding portion of the semiconductor wafer.

### SUMMARY

It is an object of the present disclosure to provide a semiconductor wafer having cut-outs in an outer peripheral surface and in a protruding portion thereof to suppress reduction in diameter of the protruding portion and to provide a method of manufacturing the semiconductor wafer.

A semiconductor wafer according to the present disclosure has a first surface and a second surface opposite the first surface. The first surface includes a first main surface and an enclosing surface. The enclosing surface encloses a perimeter of the first main surface via a stepped surface and is set back from the first main surface toward the second surface. The semiconductor wafer according to the present disclosure has a first cut-out and a second cut-out. The first cut-out is in a portion in a circumferential direction of the stepped surface connecting the first main surface and the enclosing surface. The second cut-out is in portion in a circumferential direction of an outer peripheral surface connecting the second surface and the enclosing surface. The first cut-out is in the form of an orientation flat, and the second cut-out is in the form of a notch.

A method of manufacturing a semiconductor wafer according to the present disclosure includes a preparation step, a protruding structure formation step, and a grinding step. In the preparation step, a semiconductor wafer having a first surface and a second surface opposite the first surface and having a second cut-out in the form of a notch in a portion in a circumferential direction of an outer peripheral surface connecting the first surface and the second surface is prepared. In the protruding structure formation step, a portion of the first surface of the semiconductor wafer corresponding to an enclosing surface enclosing a perimeter of a first main surface via a stepped surface and being set back from the first main surface toward the second surface is cut so that the first surface includes the first main surface and the enclosing surface. In the grinding step, cutting is performed to form a first cut-out in the form of an orientation flat in a portion in a circumferential direction of the stepped surface connecting the first main surface and the enclosing surface.

According to the semiconductor wafer and the method of manufacturing the semiconductor wafer according to the present disclosure, the semiconductor wafer has the notch in the outer peripheral surface thereof, a width in the circumferential direction of the notch is smaller than a width of the orientation flat, so that the enclosing surface and the first cut-out can be ground from above the notch using a grindstone larger than the width of the notch, and a radial width of the enclosing surface and a depth on a side of an inner diameter of the first cut-out can be reduced. Reduction in diameter of the protruding portion can thereby be suppressed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a top view illustrating a semiconductor wafer according to Embodiment 1;

FIG. 2 is a schematic cross-sectional view of the semiconductor wafer according to Embodiment 1;

FIG. 3 is a top view of the semiconductor wafer according to Embodiment 1 before being processed;

FIG. 4 is a schematic cross-sectional view of the semiconductor wafer according to Embodiment 1 before being processed;

FIG. 5 is a schematic cross-sectional view of a semiconductor wafer according to a modification of Embodiment 1;

FIG. 6 is a top view of a divided semiconductor wafer on a side of a first main surface according to Embodiment 1;

FIG. 7 is a top view of a divided semiconductor wafer on a side of a second surface according to Embodiment 1;

FIG. 8 is a schematic cross-sectional view of the divided semiconductor wafer on the side of the first main surface according to Embodiment 1;

FIG. 9 is a schematic cross-sectional view of the divided semiconductor wafer on the side of the second surface according to Embodiment 1;

FIG. 10 is a schematic cross-sectional view of a divided semiconductor wafer on a side of a first main surface according to a comparative example of Embodiment 1;

FIG. 11 is a schematic cross-sectional view of a divided semiconductor wafer on a side of a second surface according to the comparative example of Embodiment 1;

FIG. 12 is a schematic cross-sectional view of a semiconductor wafer including two members bonded together according to a modification of Embodiment 1;

FIG. 13 is a schematic cross-sectional view of a semiconductor wafer including two members bonded together according to a modification of Embodiment 1;

FIG. 14 is a schematic cross-sectional view of a semiconductor wafer including two members bonded together according to a modification of Embodiment 1; and

FIG. 15 is a flowchart of a method of manufacturing a semiconductor wafer according to Embodiment 1.

### DESCRIPTION OF THE PREFERRED EMBODIMENTS

### 1. Embodiment 1

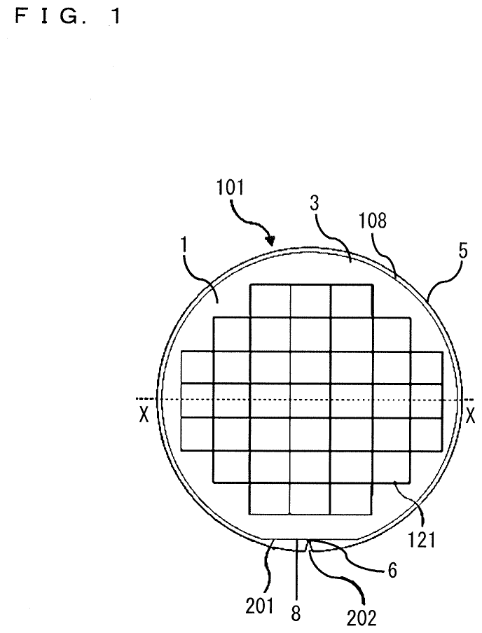

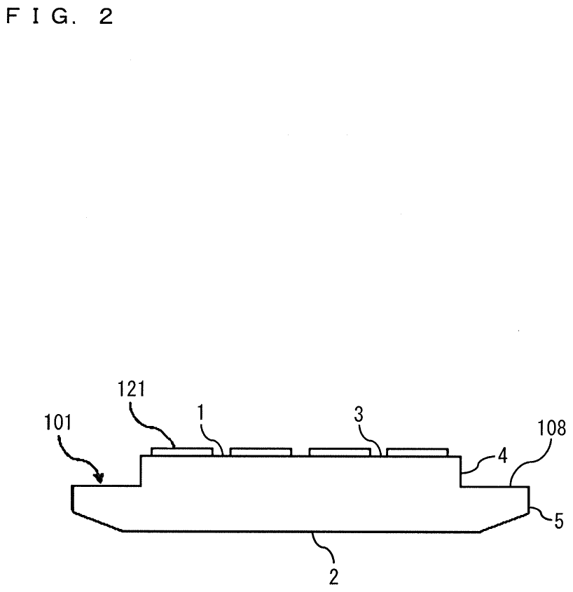

A semiconductor wafer 101 according to Embodiment 1 will be described with reference to the drawings. FIG. 1 is a top view illustrating the semiconductor wafer 101 according to Embodiment 1. FIG. 2 is a schematic cross-sectional view of the semiconductor wafer 101 according to Embodiment 1. Each cross-sectional view is a cross-sectional view taken along the line X-X of FIG. 1 or the like. Each schematic cross-sectional view is a diagram for schematically describing features of each part, and dimensions of each part in each schematic cross-sectional view do not match dimensions of each part in each top view.

### 1-1. Configuration of Semiconductor Wafer

The semiconductor wafer 101 is a semiconductor wafer 101 having a first surface 1 and a second surface 2 opposite the first surface 1, wherein the first surface 1 includes a first main surface 3 and an enclosing surface 108 enclosing a perimeter of the first main surface 3 via a stepped surface 4 and being set back from the first main surface 3 toward the second surface 2, the semiconductor wafer 101 has a first cut-out 201 in a portion in a circumferential direction of the stepped surface 4 between the first main surface 3 and the enclosing surface 108, the semiconductor wafer 101 has a second cut-out 202 in a portion in a circumferential direction of an outer peripheral surface 5 between the second surface 2 and the enclosing surface 108, and the first cut-out 201 is in the form of an orientation flat, and the second cut-out 202 is in the form of a notch.

### Semiconductor Wafer

While description will be made in the present embodiment on a case where the semiconductor wafer 101 includes a silicon carbide single crystal, the semiconductor wafer 101 may include another semiconductor material or a ceramic material. The semiconductor material includes silicon, a gallium nitride-based material, a gallium oxide-based material, or diamond, for example. The ceramic material includes A-AL₂O₃ (sapphire), for example.

When silicon carbide is used, silicon carbide may be 15R-SIC (15R silicon carbide) or hexagonal polytype silicon carbide, such as 2H-SIC (2H type silicon carbide), 4H-SIC (4H type silicon carbide), and 6H-SIC (6H type silicon carbide), or may be a polycrystalline body or a sintered body. A dopant atom may include nitrogen N, phosphorus P, beryllium BE, boron B, aluminum AL, and gallium GA, for example. An unnecessary impurity, such as hydrogen, fluorine, and oxygen, may further be included.

The semiconductor wafer 101 may have an off-axis angle in the C-plane. The off-axis angle is preferably in an A-axis direction ([11-20] direction) of the silicon carbide single crystal. The off-axis angle may be more than 0° and 10° or less and is more preferably 2° or more and 4.5° or less.

A diameter of the semiconductor wafer 101 may correspond to production criteria and may be 2 in, 3 in, 4 in, 5 in, 6 in, 7 in, 8 in, or 12 in. The semiconductor wafer 101 has a thickness of 0.1 mm or more and 50 mm or less and typically has a thickness of 20 mm or less. When a wafer for device formation cut out of a silicon carbide ingot is used, the wafer has a thickness of 0.2 mm or more and 15 mm or less, preferably has a thickness of 10 mm or less, and more preferably has a thickness of 1 mm or less.

An epitaxial film may be formed over the semiconductor wafer 101, and a semiconductor element structure 121 may be formed over the epitaxial film. Formation of the semiconductor element structure 121 includes ion implantation and formation of a surface electrode. The semiconductor element structure 121 is a power device structure, such as a metal-oxide-semiconductor field-effect transistor (MOSFET), a diode, and an insulated gate bipolar transistor (IGBT). When a gallium nitride wafer is used in place of a silicon carbide wafer, the semiconductor element structure 121 is a gallium nitride (GAN) high-frequency device structure, for example, and the gallium nitride high-frequency device structure may be formed over the silicon carbide wafer.

First Main surface and Enclosing Surface

The semiconductor wafer 101 is the semiconductor wafer 101 having the first surface 1 and the second surface 2 opposite the first surface 1, and the first surface 1 includes the first main surface 3 and the enclosing surface 108 enclosing the perimeter of the first main surface 3 via the stepped surface 4 and being set back from the first main surface 3 toward the second surface 2.

The first main surface 3 has a protruding shape having a smaller diameter than the second surface 2, and the first cut-out 201 is in a portion of an outer periphery on a side of the first main surface 3 and the second cut-out 202 is in a portion of the outer periphery on a side of the second surface 2.

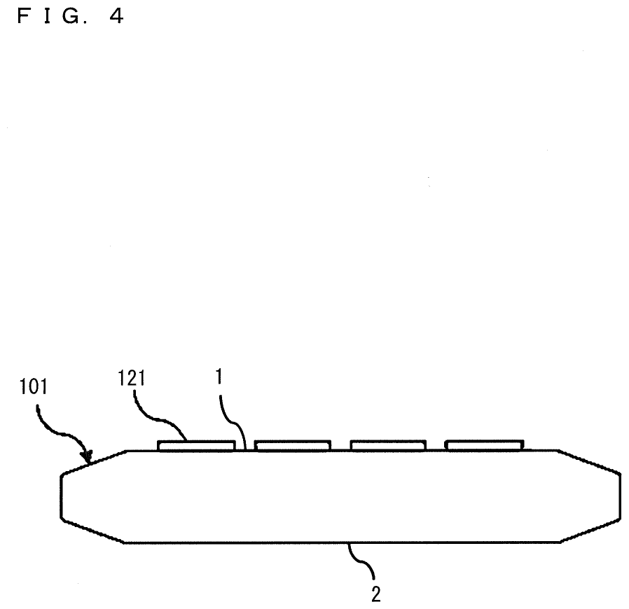

An outer peripheral portion of the semiconductor wafer 101 before being ground illustrated in a schematic cross-sectional view of FIG. 4 is ground partway in a thickness direction from the first surface 1 toward the second surface 2, so that the semiconductor wafer 101 has a protruding structure as illustrated in the schematic cross-sectional view of FIG. 2.

As described above, the semiconductor wafer 101 has the protruding shape and has the first main surface 3 and the enclosing surface 108, the first main surface 3 is located at a higher position than the enclosing surface 108, and the enclosing surface 108 is located to enclose the first main surface 3. The first surface 1 includes the enclosing surface 108 and the first main surface 3, and the thickness includes a thickness on a side of the first main surface 3 as a thickness between the first main surface 3 and the enclosing surface 108 and a thickness on a side of the enclosing surface as a thickness between the enclosing surface 108 and the second surface 2.

The thickness on the side of the enclosing surface and the thickness on the side of the first main surface 3 of the thickness between the first surface 1 and the second surface 2 differ from each other. The thickness on the side of the enclosing surface is preferably 0.05 mm or more and 50 mm or less and is more preferably 0.15 mm or less. The thickness on the side of the second surface 2 is 0.05 mm or more and 50 mm or less and is more preferably 0.15 mm or less.

The thickness on the side of the enclosing surface is preferably greater than the thickness on the side of the first main surface 3 to suppress cracking and breakage at an end, and the thickness on the side of the first main surface 3 is preferably 100 μm to 200 μm to maintain strength after division. For example, when the wafer has a total thickness of 350 μm, the thickness on the side of the enclosing surface is 200 μm to 250 μm and the thickness on the side of the first main surface 3 is 100 μm to 150 μm, and, when the wafer has a total thickness of 500 μm, the thickness on the side of the enclosing surface is 300 μm to 400 μm and the thickness on the side of the first main surface 3 is 100 μm to 200 μm.

A difference in diameter between the first main surface 3 and the second surface 2 is preferably less than 2 mm and is more preferably less than 0.5 mm. The difference in diameter of less than 0.5 mm eliminates the need for adjustment of the diameter of the device when the semiconductor wafer 101 is divided to reprocess the semiconductor wafer on a side on which the semiconductor element structure 121 has not been formed to form the semiconductor element structure 121, which will be described below.

### First Cut-Out and Second Cut-Out

The semiconductor wafer 101 has the first cut-out 201 in a portion in a circumferential direction of the stepped surface 4 between the first main surface 3 and the enclosing surface 108 and has the second cut-out 202 in a portion in a circumferential direction of the outer peripheral surface 5 between the second surface 2 and the enclosing surface 108.

As illustrated in the top view of FIG. 1, in the present embodiment, when viewed perpendicularly to the first main surface 3, a bottom point 6 of the second cut-out 202 in the form of the notch and a cut-out surface 8 of the first cut-out 201 in the form of the orientation flat overlap each other. When viewed perpendicularly to the first main surface 3, a portion of the cut-out surface 8 of the first cut-out 201 in the form of the orientation flat closest to the bottom point 6 of the second cut-out 202 in the form of the notch is a middle portion of the cut-out surface 8 of the first cut-out 201. According to this configuration, a width of the enclosing surface 108 can be reduced to be smaller than or equal to a depth of the second cut-out 202 in the form of the notch, a depth of the first cut-out 201 can be reduced to be smaller than or equal to the depth of the second cut-out 202 in the form of the notch, and the diameter of the first main surface 3 can be increased. A width in a circumferential direction of the notch is smaller than a width of the orientation flat, so that the enclosing surface 108 and the first cut-out 201 can be ground from above the notch using a grindstone larger than the width of the notch, and a radial width of the enclosing surface 108 and a depth on a side of an inner diameter of the first cut-out 201 can be reduced. When the second cut-out 202 is in the form of an orientation flat as in Japanese Patent Application Laid-Open No. 2021-52178, the orientation flat has a greater width, so that the enclosing surface 108 and the first cut-out 201 cannot be ground from above the orientation flat, and the first cut-out 201 is required to be formed inside the orientation flat, and thus the first cut-out 201 has a greater depth and the first main surface 3 has a smaller diameter.

When viewed perpendicularly to the first main surface 3, a shortest distance between the bottom point 6 of the second cut-out 202 in the form of the notch and the cut-out surface 8 of the first cut-out 201 in the form of the orientation flat may be smaller than or equal to the depth of the second cut-out 202. According to this configuration, even if there is some distance, the width of the enclosing surface 108 and the depth of the first cut-out 201 can be reduced, and the diameter of the first main surface 3 can be increased.

The number of cut-outs may not be one on each of the side of the first main surface 3 and the side of the second surface 2 and may be two or more. For example, when another orientation flat is formed at a position 90° different from the first cut-out 201 in the circumferential direction, a particular crystal orientation and a conductivity type (a P type or an N type) of the semiconductor wafer 101 are easily determined. The first cut-out 201 and the second cut-out 202 may be formed at the same position or may be formed at different positions. The first cut-out 201 and the second cut-out 202, however, preferably coincide with each other as a cut-out indicates a crystal orientation.

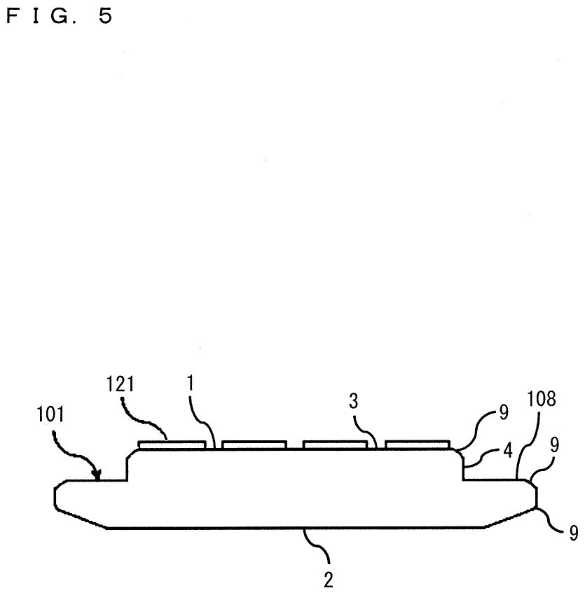

As illustrated in FIG. 5, the semiconductor wafer 101 may have rounded corners 9. The rounded corners 9 suppress chipping and breakage occurring due to stress concentration at the end and can increase the strength of the semiconductor wafer 101. Each chamfer has a radius in a range of 0.5 μm to 50 μm and more preferably has a radius in a range of 5 μm to 20 μm. The chamfer may be controlled by a shape of the grindstone used for trimming and is sometimes formed unintentionally by a change in shape of the grindstone due to wear of the grindstone. The chamfer may alternatively be formed by etching.

### 1-2. Method of Manufacturing Semiconductor Wafer

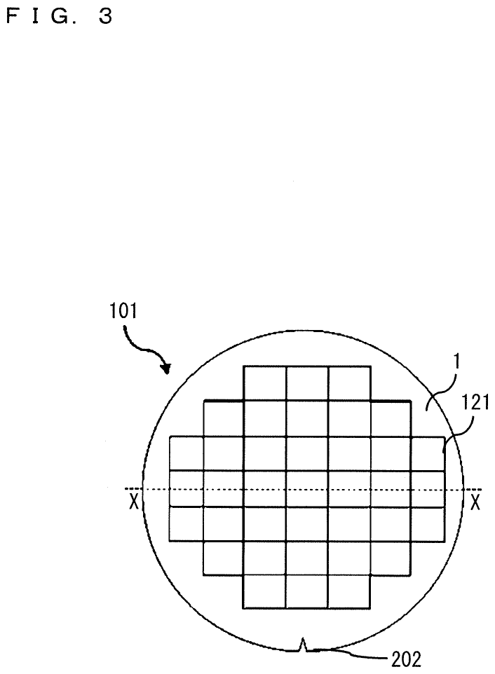

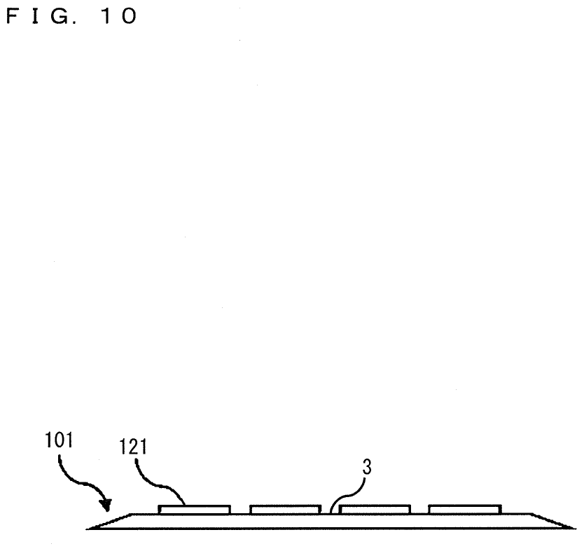

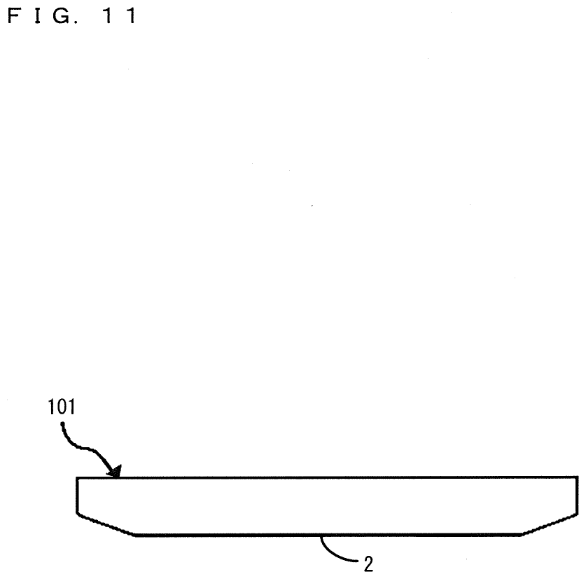

In a comparative example, when the typical semiconductor wafer 101 including the semiconductor element structure 121 illustrated in a top view of FIG. 3 and in the schematic cross-sectional view of FIG. 4 is divided into a portion on a side of the first surface 1 and a portion on a side of the second surface 2, the semiconductor wafer 101 is divided into a wafer 101 with the semiconductor element including the semiconductor element structure 121 illustrated in a schematic cross-sectional view of FIG. 10 and a semiconductor wafer 101 not including the semiconductor element illustrated in a schematic cross-sectional view of FIG. 11. As illustrated in FIG. 10, the wafer 101 with the semiconductor element according to the comparative example does not have the protruding structure and thus has a sharp edge. The sharp edge increases the likelihood of chipping and breakage occurring due to stress concentration at the end.

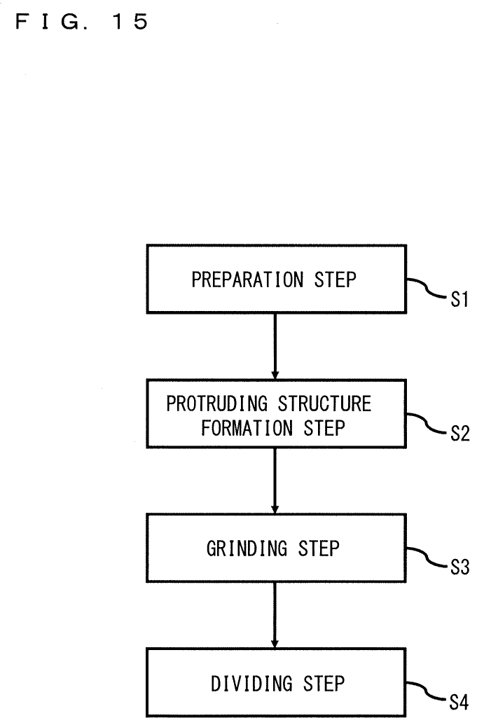

FIG. 15 shows a flowchart of a method of manufacturing the semiconductor wafer 101 according to Embodiment 1.

### Preparation Step S1

As illustrated in the top view of FIG. 3 and in the schematic cross-sectional view of FIG. 4, in a preparation step, the semiconductor wafer 101 having the first surface 1 and the second surface 2 opposite the first surface 1 and having the second cut-out 202 in the form of the notch in the portion in the circumferential direction of the outer peripheral surface 5 connecting the first surface 1 and the second surface 2 is prepared. In FIGS. 3 and 4, the semiconductor wafer 101 including the semiconductor element structure 121 on the first surface 1 is prepared. The structure of the semiconductor wafer 101, however, may be formed after a grinding step S3 or a dividing step S4.

### Protruding Structure Formation Step S2

As illustrated in the schematic view of FIG. 2, in a protruding structure formation step S2, a portion of the first surface 1 of the semiconductor wafer 101 corresponding to the enclosing surface 108 enclosing the perimeter of the first main surface 3 via the stepped surface 4 and being set back from the first main surface 3 toward the second surface 2 is cut so that the first surface 1 includes the first main surface 3 and the enclosing surface 108. The semiconductor wafer 101 having the second cut-out 202 in the portion in the circumferential direction of the outer peripheral surface 5 connecting the first surface 1 and the second surface 2 is ground partway from the first main surface 3 toward the second surface 2.

### Grinding Step S3

In the grinding step S3, cutting is performed to form the first cut-out 201 in the form of the orientation flat in the portion in the circumferential direction of the stepped surface 4 connecting the first main surface 3 and the enclosing surface 108.

The protruding structure formation step S2 and the grinding step S3 are performed using the same cutting apparatus. With this configuration, a manufacturing cost can be reduced. For example, an apparatus including a rotary edger and a grinding grindstone attached to the rotary edger is used in the protruding structure formation step S2 and in the grinding step S3. As the grinding grindstone, a grindstone having been adjusted to be able to grind an outer periphery of the first surface 1 from above the first surface 1 is used. Using a grindstone larger than the width of the notch as the second cut-out 202, the enclosing surface 108 and the first cut-out 201 can be ground from above the notch.

The outer periphery of the first surface 1 may be half cut using a dicing apparatus to form the enclosing surface 108 and the first cut-out 201. In any of the methods, the same grindstone as that used for trimming of the enclosing surface 108 can be used as the grindstone to process the first cut-out 201. Such processing enables formation of the orientation flat having an end inside an end of the notch.

### Dividing Step S4

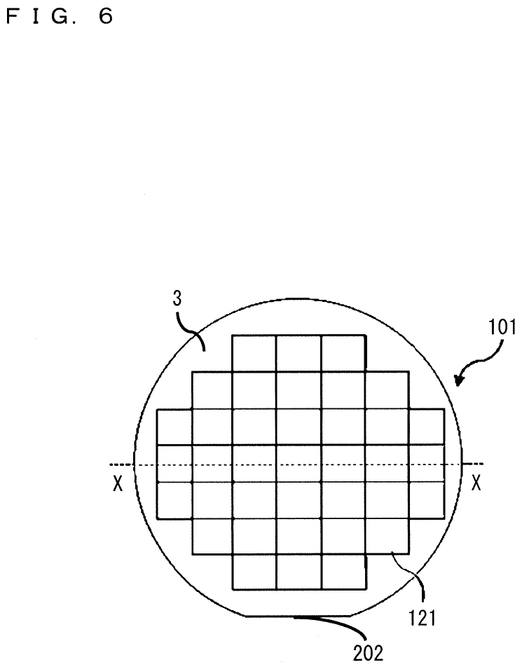

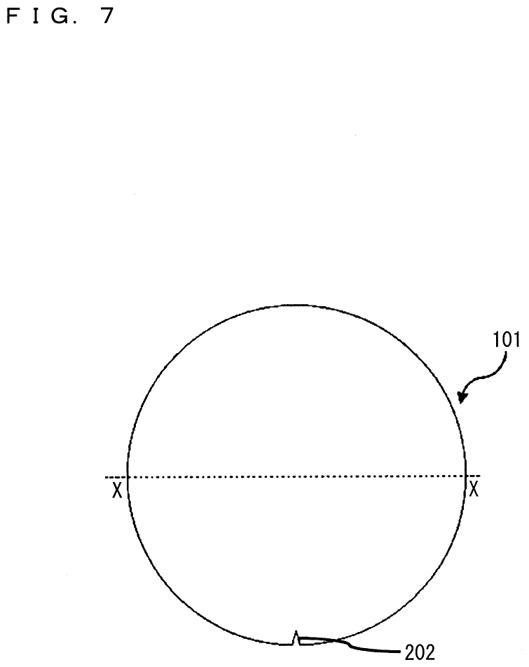

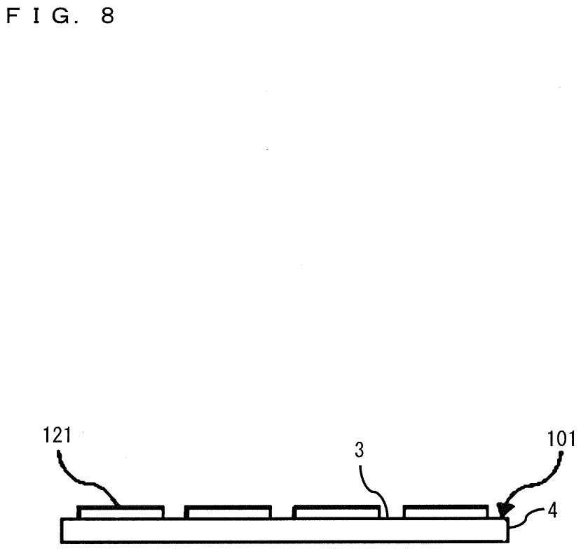

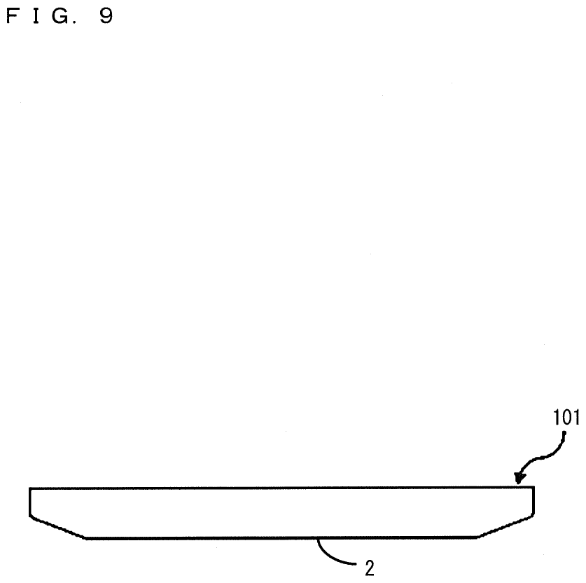

In the dividing step S4, the semiconductor wafer 101 is cut in the same pane as the enclosing surface 108 to divide the semiconductor wafer 101 into the semiconductor wafer 101 on the side of the first main surface 3 and the semiconductor wafer 101 on the side of the second surface 2. The semiconductor wafer 101 is thereby separated into the semiconductor wafer 101 on the side of the first main surface 3 illustrated in a top view of FIG. 6 and in a schematic cross-sectional view of FIG. 8 and the semiconductor wafer 101 on the side of the second surface 2 illustrated in a top view of FIG. 7 and in a schematic cross-sectional view of FIG. 9. The protruding structure is formed as illustrated in FIG. 8, so that the sharp edge can be prevented to reduce the likelihood of chipping and breakage in contrast to the comparative example in FIG. 10. The semiconductor wafer 101 on the side of the first main surface 3 can have a smaller diameter as described above.

Semiconductor wafers 101 on the side of the first main surface 3 can be aligned by the orientation flat when being processed by a semiconductor manufacturing apparatus. This eliminates the need for formation of a cut-out for positioning by additional processing of the semiconductor wafer 101 on the side of the first main surface 3. The semiconductor wafer 101 on the side of the second surface 2 has the same diameter as the semiconductor wafer 101 before division, and the diameter of the device is not required to be adjusted when the semiconductor wafer 101 on the side of the second surface 2 is reprocessed to form the semiconductor element. The notch enables alignment by the notch during processing performed by the semiconductor manufacturing apparatus. This eliminates the need for formation of a cut-out for positioning by additional processing of the semiconductor wafer 101 on the side of the second surface 2.

The semiconductor wafer 101 may be divided into the semiconductor wafer 101 on the side of the first main surface 3 and the semiconductor wafer 101 on the side of the second surface 2 by a contact method of contacting the semiconductor wafer 101 by a dicing saw and the like or a non-contact method of using an optical scheme.

### Modifications

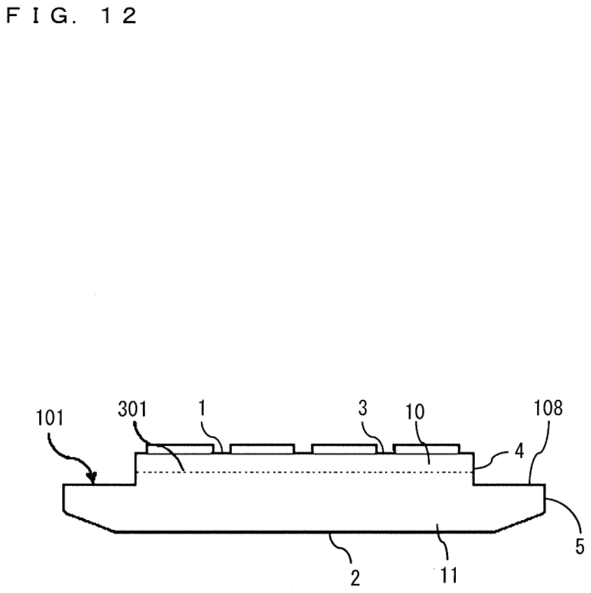

As illustrated in schematic cross-sectional views of FIGS. 12 to 14, the semiconductor wafer 101 may include a member on the side of the first surface and a member on the side of the second surface 2 bonded together.

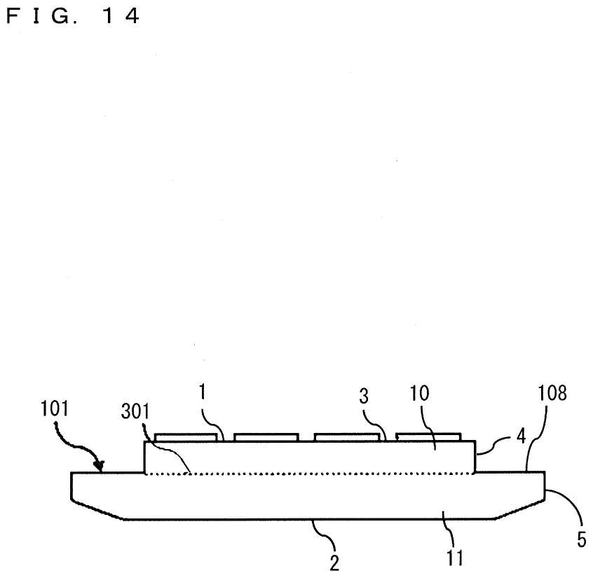

For example, as illustrated in the schematic cross-sectional view of FIG. 14, an interface 301 between a member 10 on the side of the first main surface and a member 11 on the side of the second surface may be flush with the enclosing surface 108.

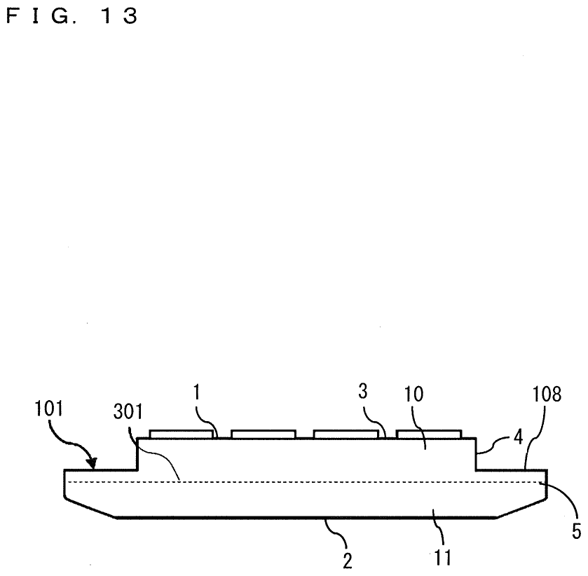

Alternatively, as illustrated in the schematic cross-sectional view of FIG. 13, in the semiconductor wafer 101, the interface 301 between the member 10 on the side of the first main surface and the member 11 on the side of the second surface may be located closer to the second surface 2 than the enclosing surface 108 is.

Alternatively, as illustrated in the schematic cross-sectional view of FIG. 12, in the semiconductor wafer 101, the interface 301 between the member 10 on the side of the first main surface and the member 11 on the side of the second surface may be located closer to the first main surface 3 than the enclosing surface 108 is.

For example, technology by cold bonding is used to bond two types of members. A clean interface without including a metal layer and the like at the interface 301 can be obtained by cold bonding. When cold bonding is used, an amorphous layer may be formed at the interface 301. The amorphous layer preferably has a thickness of 5 μm or less and more preferably has a thickness of 0.1 μm or less.

The member on the side of the first main surface 3 and the member on the side of the second surface 2 each include a single crystal. A configuration in which one of the member on the side of the first main surface 3 and the member on the side of the second surface 2 includes a single crystal and the other one of the member on the side of the first main surface 3 and the member on the side of the second surface 2 includes polycrystals may be used. The semiconductor wafer 101 can be formed inexpensively when polycrystalline substrates and wafers including different materials are used compared with a case where wafers each including a single crystal are bonded together. When two types of members are subjected to high temperature processing and implantation processing, a wafer bows due to stress during processing, so that it is preferable to bond materials having relatively close physical properties. As the physical properties, a coefficient of thermal expansion, a melting point, and the like are included in selection factors when materials for the members are selected.

After the two types of members are bonded together, a protruding structure having the same first cut-out 201 and the same second cut-out 202 as those of the semiconductor wafer 101 is formed using the rotary edger or the dicing apparatus by the above-mentioned manufacturing method. Alternatively, wafers originally having different diameters and different cut-outs may be bonded together to form the same structure as the semiconductor wafer 101.

Although a case where the two types of members are bonded together to form the semiconductor wafer 101 has been described, three or more types of members may be bonded together to form the semiconductor wafer 101.

While the disclosure has been shown and described in detail, the foregoing description is in all aspects illustrative and not restrictive. It is therefore understood that numerous modifications and variations can be devised.

What is claimed is:

1. A semiconductor wafer having a first surface and a second surface opposite the first surface, wherein
the first surface includes a first main surface and an enclosing surface enclosing a perimeter of the first main surface via a stepped surface and being set back from the first main surface toward the second surface,
the semiconductor wafer has a first cut-out in a portion in a circumferential direction of the stepped surface connecting the first main surface and the enclosing surface,
the semiconductor wafer has a second cut-out in a portion in a circumferential direction of an outer peripheral surface connecting the second surface and the enclosing surface, and
the first cut-out is in the form of an orientation flat, and the second cut-out is in the form of a notch.

2. The semiconductor wafer according to claim 1, wherein
when viewed perpendicularly to the first main surface, a shortest distance between a bottom point of the second cut-out in the form of the notch and a cut-out surface of the first cut-out in the form of the orientation flat is smaller than or equal to a depth of the second cut-out.

3. The semiconductor wafer according to claim 1, wherein
when viewed perpendicularly to the first main surface, a bottom point of the second cut-out in the form of the notch and a cut-out surface of the first cut-out in the form of the orientation flat overlap each other.

4. The semiconductor wafer according to claim 1, wherein
when viewed perpendicularly to the first main surface, a portion of a cut-out surface of the first cut-out in the form of the orientation flat closest to a bottom point of the second cut-out in the form of the notch is a middle portion of the cut-out surface of the first cut-out.

5. The semiconductor wafer according to claim 1, wherein the semiconductor wafer comprises one member.

6. The semiconductor wafer according to claim 1, wherein
the semiconductor wafer comprises a member on a side of the first main surface and a member on a side of the second surface bonded together.

7. The semiconductor wafer according to claim 6, wherein
an interface between the member on the side of the first main surface and the member on the side of the second surface is flush with the enclosing surface.

8. The semiconductor wafer according to claim 6, wherein
an interface between the member on the side of the first main surface and the member on the side of the second surface is located closer to the second surface than the enclosing surface is.

9. The semiconductor wafer according to claim 6, wherein
an interface between the member on the side of the first main surface and the member on the side of the second surface is located closer to the first main surface than the enclosing surface is.

10. The semiconductor wafer according to claim 1, wherein
a member on a side of the first main surface and a member on a side of the second surface each comprise a single crystal.

11. The semiconductor wafer according to claim 1, wherein
one of a member on a side of the first main surface and a member on a side of the second surface comprises a single crystal, and the other one of the member on the side of the first main surface and the member on the side of the second surface comprises polycrystals.

12. The semiconductor wafer according to claim 1, wherein
the semiconductor wafer has a rounded corner.

13. A method of manufacturing a semiconductor wafer, the method comprising:
a preparation step of preparing a semiconductor wafer having a first surface and a second surface opposite the first surface and having a second cut-out in the form of a notch in a portion in a circumferential direction of an outer peripheral surface connecting the first surface and the second surface;
a protruding structure formation step of cutting a portion of the first surface of the semiconductor wafer corresponding to an enclosing surface so that the first surface includes a first main surface and the enclosing surface, the enclosing surface enclosing a perimeter of the first main surface via a stepped surface and being set back from the first main surface toward the second surface; and
a grinding step of performing cutting to form a first cut-out in the form of an orientation flat in a portion in a circumferential direction of the stepped surface connecting the first main surface and the enclosing surface.

14. The method of manufacturing the semiconductor wafer according to claim 13, wherein
the protruding structure formation step and the grinding step are performed using the same cutting apparatus.
